(19) United States
(12) Patent Application Publication
(10) Pub. No.: US 2014/0103419 A1
(43) Pub. Date: Apr. 17, 2014

(54) NON-VOLATILE MEMORY DEVICE AND METHOD FOR FORMING THE SAME

(71) Applicant: Eon Silicon Solution Inc., Chu-Pei City (TW)

(72) Inventors: Wen-Cheng LEE, New Taipei City (TW); Yi-Hsi CHEN, Zhubei City (TW); Yi-Der WU, Chupei City (TW)

(21) Appl. No.: 13/919,365

(22) Filed: Jun. 17, 2013

(30) Foreign Application Priority Data
Oct. 15, 2012 (TW) 101137949

(51) Int. Cl. H01L 27/115

(52) U.S. Cl. CPC H01L 27/11563
USPC 257/325; 438/279

(57) ABSTRACT

A method for forming a non-volatile memory device includes: (a) forming an isolation structure on a circuit-forming surface of a semiconductor substrate to define an array of cell forming regions; (b) forming a gate structure array including a plurality of gate structures disposed above the cell forming regions and each having a first side and a second side; (c) performing ion implantation to form drain regions and a common source region; and (d) forming drain contacts to the drain regions, and a common source contact to the common source region.

### CROSS-REFERENCE TO RELATED APPLICATION

This application claims priority to Taiwanese Application No. 101137949, filed on Oct. 15, 2012.

### BACKGROUND OF THE INVENTION

1. Field of the Invention

This invention relates to a memory device, and more particularly to a non-volatile memory device.

2. Description of the Related Art

With the advancements in memory fabrication, from booting electronic devices to data storage, non-volatile memory devices have been applied into a wide variety of applications. Among all the non-volatile memory devices, flash memory is one of the most popular. A conventional flash memory has a floating gate structure and usually contains a memory cell array that is formed on a substrate and that includes a plurality of memory cells. Each of the memory cells is a transistor having a control gate, a floating gate, a source region and a drain region, wherein the floating gate for trapping electrons therein is separated from the source and drain regions by a tunneling dielectric layer. That is, by applying voltages on the control gate to drive electrons through the tunneling dielectric layer and to charge the floating gate, each of the memory cells can be programmed or written with respect to the existence of electrons in the floating gate thereof.

In U.S. Pat. No. 6,784,061, two types of flash memory devices are disclosed to utilize common source lines (Vss lines) embedded in the semiconductor substrate, or above the semiconductor substrate in conjunction with source contacts to interconnect the source regions of the memory cells.

However, lowering the writing/programming voltages is one of current issues that need to be addressed. A conventional method to overcome the issue is to lower the thickness of the tunneling dielectric layer, but such method results in serious leakage currents and may cause data loss of the memory cells.

Thus, another flash memory structure, i.e., polySi—SiO₂—Si₃N₄—SiO₂—Si structure (abbreviated as SONOS hereinafter) has been adopted for alleviating the leakage current issue while lowering the thickness of the tunneling dielectric layer. Referring to FIG. 1, a conventional SONOS flash memory device includes a substrate 1, a plurality of isolation strips 2, a plurality of word lines 6 (only one is shown), a plurality of source regions 5 and drain regions 4, a plurality of memory cells 7, and a plurality of source contacts 51 and drain contracts 41 each of which is formed on a corresponding one of the source regions 5 and the drain regions 4.

It is expected that with the decreasing characteristic size of the memory fabrication, further development of the memory fabrication will be hindered under the current SONOS structure of the conventional flash memory device, since each memory cell 7 has their own source contacts 51 and drain contacts 41 that will restrain the sizes of the corresponding source regions 5 and drain regions 4.

### SUMMARY OF THE INVENTION

Therefore, the object of the present invention is to provide a non-volatile memory device that may alleviate the abovementioned drawbacks of the prior art.

Accordingly, a method for forming a non-volatile memory device of this invention includes the following steps of:

a) forming an isolation structure on a circuit-forming surface of a semiconductor substrate to define an array of cell forming regions, the cell forming regions including a pair of first and second cell forming regions and a pair of third and fourth cell forming regions, the first and second cell forming regions being aligned in a first direction, the third and fourth cell forming regions being aligned in the first direction, the first and third cell forming regions being aligned in a second direction transverse to the first direction, the second and fourth cell forming regions being aligned in the second direction, the isolation structure including first and second isolation strips embedded from the circuit-forming surface of the semiconductor substrate and aligned in the second direction, the first isolation strip being disposed between the first and third cell forming regions, the second isolation strip being disposed between the second and fourth cell forming regions, the first and second isolation strips respectively having distal ends that are adjacent to each other and that are disconnected from each other to define an isolation-structure-free gap therebetween, the isolation-structure-free gap being filled with a material of the semiconductor substrate, the isolation structure further defining a common-source forming region on the circuit-forming surface of the semiconductor substrate, the common-source forming region being defined by first and second imaginary lines each extending in the second direction and passing through the distal end of a respective one of the first and second isolation strips, the common-source forming region being contiguous with the first, second, third and fourth cell forming regions;

b) forming a gate structure array on the circuit-forming surface of the semiconductor substrate, the gate structure array including a plurality of gate structures, each disposed on top of the circuit-forming surface of the semiconductor substrate above a respective one of the first, second, third and fourth cell forming regions and each having a first side adjacent to the common-source forming region and a second side opposite to the first side;

c) performing ion implantation to form drain regions and a common source region on the circuit-forming surface of the semiconductor substrate, each of the drain regions being formed at the second side of a respective one of the gate structures, the common source region being formed at the common-source forming region and extending to the first sides of the gate structures; and

d) forming drain contacts for external electrical connection to the drain regions, and a common source contact for external electrical connection to the common source region.

### BRIEF DESCRIPTION OF THE DRAWINGS

Other features and advantages of the present invention will become apparent in the following detailed description of the preferred embodiment with reference to the accompanying drawings, of which:

FIG. 1 is a top view of a conventional SONOS non-volatile memory device;

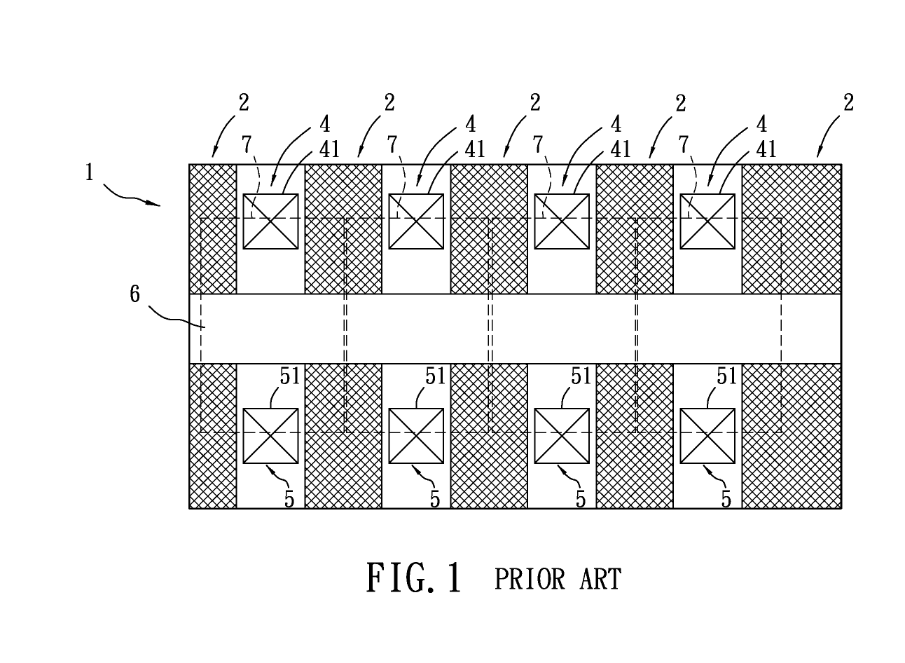

FIG. 2 is a top view of the preferred embodiment at a step 11 of a method for forming a non-volatile memory device according to the present invention, in which an isolation structure is formed;

FIG. 3 is a top view of the preferred embodiment at a step 12 of the method in which a gate structure array is formed;

FIG. 4 is a top view of the preferred embodiment at a step 13 of the method in which drain regions and a common source region are formed;

FIG. 5 is a schematic view of a memory cell of the non-volatile memory device in step 13;

FIG. 6 is a top view of the preferred embodiment at a step 14 of the method in which drain contacts and a common source contact are formed;

FIG. 7 is a top view of a variation of the non-volatile memory device according to the present invention;

FIG. 8 is a top view of another variation of the non-volatile memory device according to the present invention;

FIG. 9 is a schematic diagram of the preferred embodiment of a memory cell of the non-volatile memory device in a programming step;

FIG. 10 is a schematic diagram of the preferred embodiment of the memory cell of the non-volatile memory device in an erasing step; and

FIG. 11 is a schematic diagram of the preferred embodiment of the memory cell of the non-volatile memory device in a reading step.

### DETAILED DESCRIPTION OF THE PREFERRED EMBODIMENT

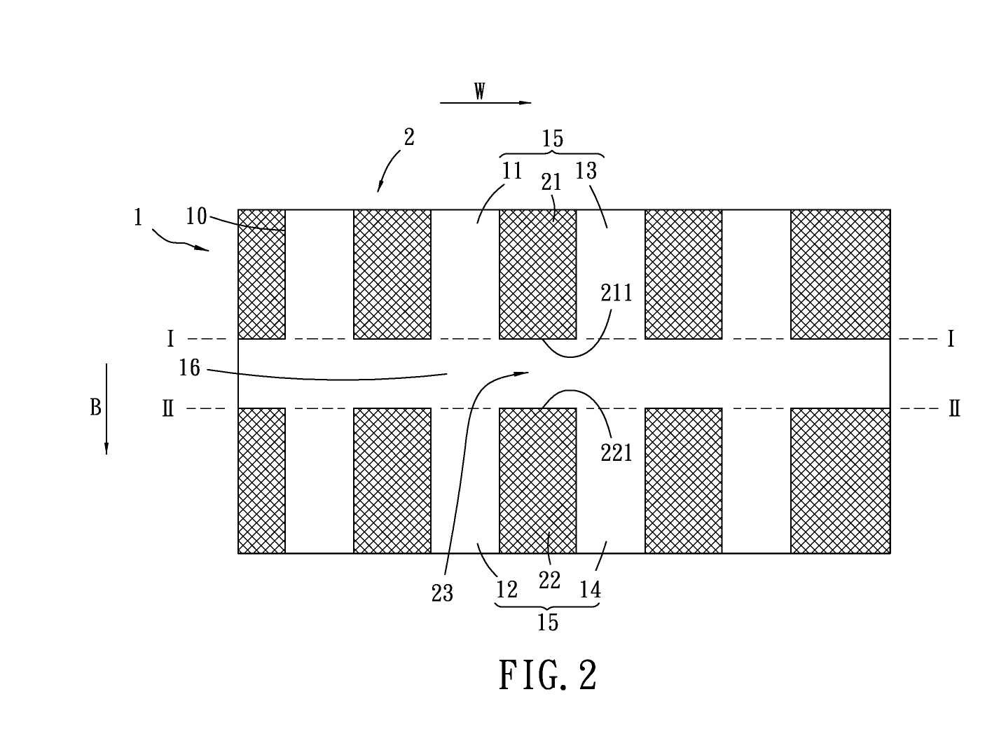

Referring to FIG. 2 to FIG. 8, the preferred embodiment of a method for forming a non-volatile memory device according to this invention includes the following steps:

Step 11: forming an isolation structure 2 (made of silicon dioxide) on a circuit-forming surface 10 of a semiconductor substrate 1 to define an array of cell forming regions 15 as shown in FIG. 2. For the sake of clarity, the cell forming regions will described herein to include a pair of first and second cell forming regions 11, 12 and a pair of third and fourth cell forming regions 13, 14. The number of the cell forming regions 15 should not be limited to the disclosure of this embodiment. In this embodiment, the first and second cell forming regions 11, 12 are aligned in a first direction B (i.e., a bit line direction), the third and fourth cell forming regions 13, 14 are aligned in the first direction B, the first and third cell forming regions 11, 13 are aligned in a second direction W (i.e., a word line direction) transverse to the first direction B, and the second and fourth cell forming regions 12, 14 are aligned in the second direction W. For the sake of clarity, the isolation structure 2 will be described herein to include first and second isolation strips 21, 22 embedded from the circuit-forming surface 10 of the semiconductor substrate 1 (such as by using shallow trench isolation techniques) and aligned in the first direction B. The first isolation strip 21 is disposed between the first and third cell forming regions 11, 13, the second isolation strip 22 is disposed between the second and fourth cell forming regions 12, 14, and the first and second isolation strips 21, 22 respectively have distal ends 211, 221 that are adjacent to each other and that are disconnected from each other to define an isolation-structure-free gap 23 therebetween. The isolation-structure-free gap 23 is filled with a material of the semiconductor substrate 1. Accordingly, the isolation structure 2 further defines a common-source forming region 16 on the circuit-forming surface 11 of the semiconductor substrate 1. To be specific, the common-source forming region 16 is defined by first and second imaginary lines I, II each extending in the second direction W and passing through the distal end 211, 221 of a respective one of the first and second isolation strips 21, 22. The common-source forming region 16 is contiguous with the first, second, third and fourth cell forming regions 11, 12, 13, and 14.

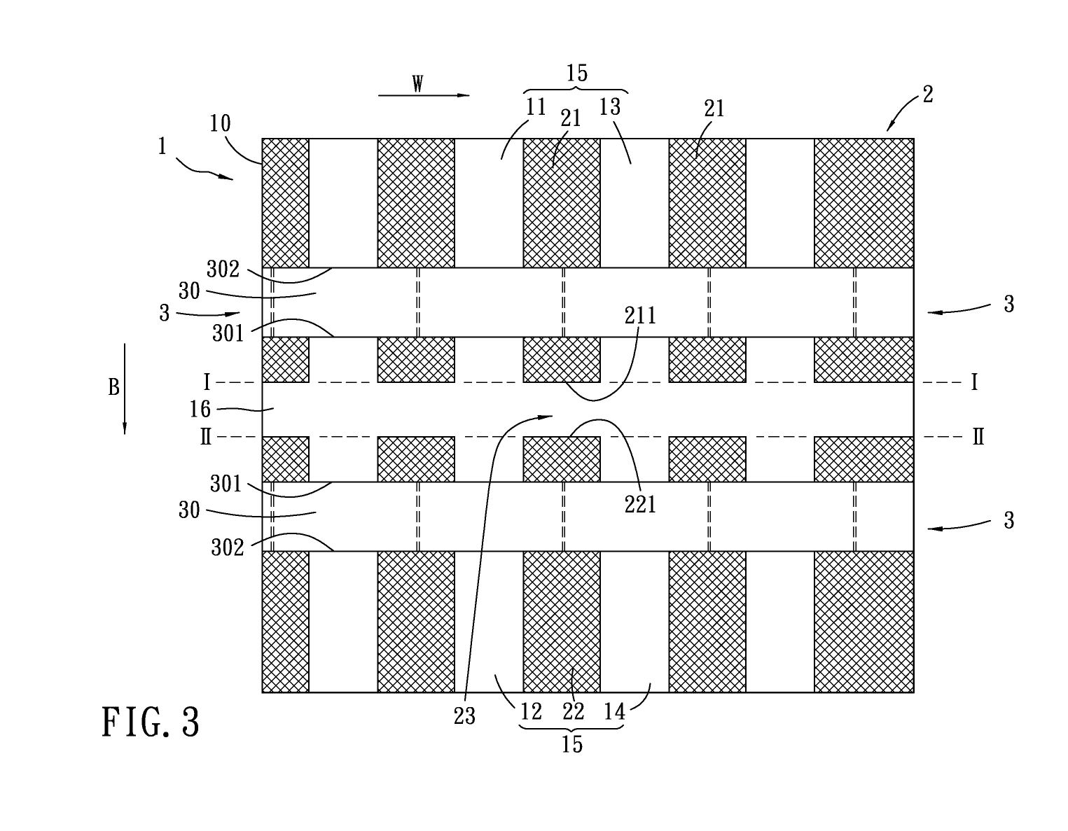

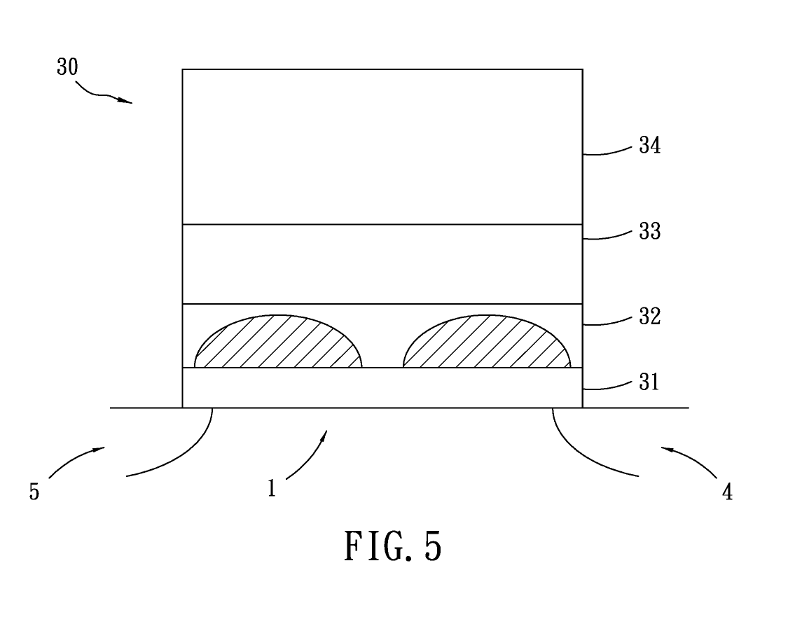

Step 12: forming a gate structure array 3 on the circuit-forming surface 10 of the semiconductor substrate 1 as shown in FIG. 3. In this step, a tunneling dielectric layer 31, a charge trapping layer 32, a dielectric layer 33 and a gate layer 34 are formed in sequence on the circuit forming surface 10 of the semiconductor substrate 1, as best shown in FIG. 5. Preferably, the tunneling dielectric layer 31 is formed on the circuit-forming surface 10 of the semiconductor substrate 1 via a thermal oxidation process. Preferably, the charge trapping layer 32 is formed on the tunneling dielectric layer 31 via a low pressure chemical vapor deposition (LPCVD) process. Preferably, the dielectric layer 33 is formed on the charge trapping layer 32 via a thermal oxidation process. The tunneling dielectric layer 31, the charge trapping layer 32 and the dielectric layer 33 cooperatively form an Oxide-Nitride-Oxide multi-layer structure. Preferably, the gate layer 34 is a polycrystalline silicon layer formed on the dielectric layer 33 using a LPCVD process.

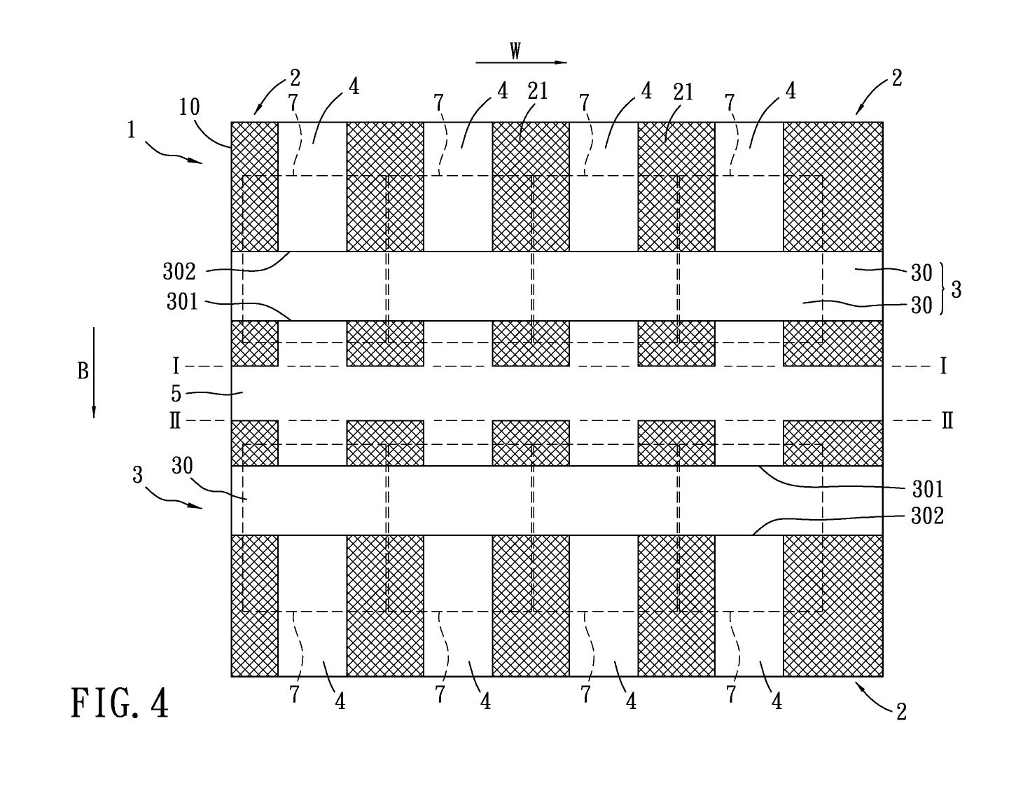

Subsequently, a photoresist mask and etching process is performed to etch the tunneling dielectric layer 31, the charge trapping layer 32, the dielectric layer 33 and the gate layer 34 to form the gate structure array 3 that includes a plurality of gate structures 30 (see FIG. 4), each disposed on top of the circuit-forming surface 10 of the semiconductor substrate 1. In this embodiment, the gate structures 30 include four gate structures 30 respectively disposed above a respective one of the first, second, third and fourth cell forming regions 11, 12, 13, 14 and each having a first side 301 adjacent to the common-source forming region 16 and a second side 302 opposite to the first side.

Step 13: performing ion implantation to form drain regions 4 and a common source region 5 on the circuit-forming surface 10 of the semiconductor substrate 1 as shown in FIG. 4 for forming memory cells 7. In this step, each of the drain regions 4 is formed at the second side 302 of a respective one of the gate structures 30, and the common source region 5 is formed at the common-source forming region 16 and extends to the first sides 301 of the gate structures 30. Formation of the drain regions 4 and the common source region 5 maybe conducted separately or concurrently using known ion implantation techniques.

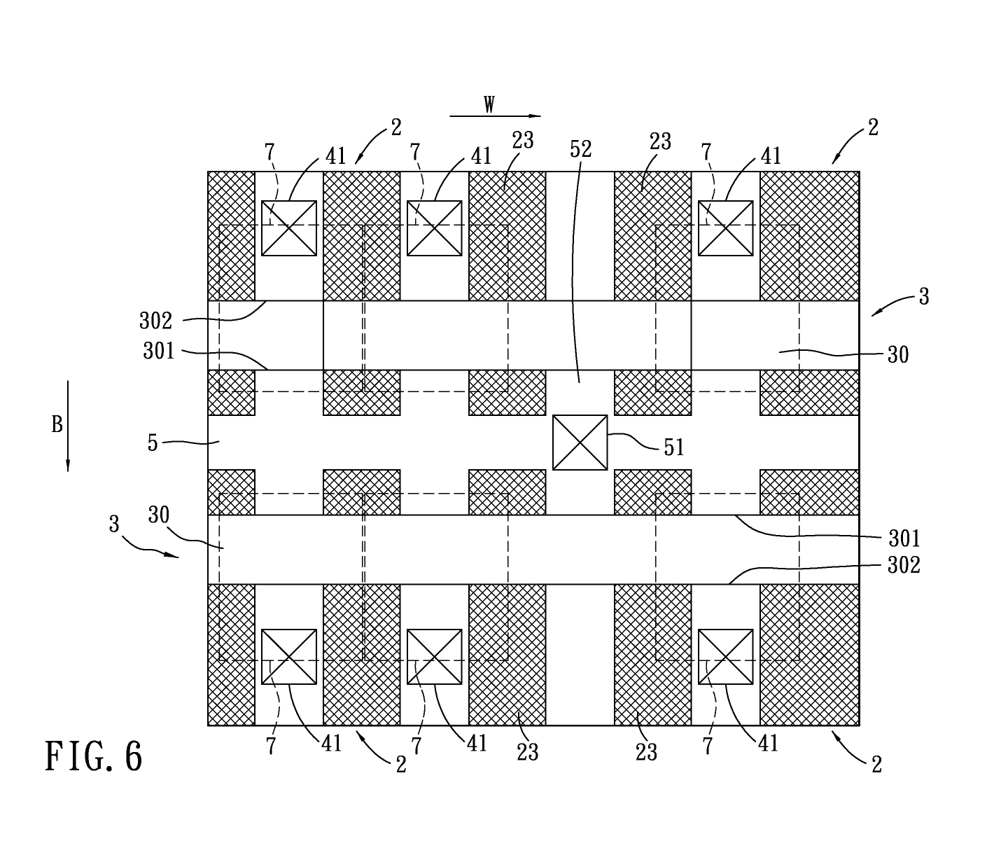

Step 14: forming drain contacts 41 for external electrical connection to the drain regions 4, and a common source contact 51 for external electrical connection to the common source region 5 as shown in FIG. 6. In this step, the drain contacts 41 and the common source contact 51 are formed through a dielectric layer (not shown in figure) that is formed over the semiconductor substrate 1 after step 13.

Therefore, the preferred embodiment of a non-volatile memory device according to the present invention comprises: a semiconductor substrate 1 having a circuit-forming surface 10; an isolation structure 2 formed on the circuit-forming surface 10 to define an array of cell forming regions 15 thereon; a gate structure array 3 formed on the circuit-forming surface 10 of the semiconductor substrate 1; drain regions 4 and a common source region 5 formed on the semiconductor substrate 1; and drain contacts 41 for external electrical connection to the drain regions 4, and a common source contact 51 for external electrical connection to the common source region 5.

The cell forming regions 15 include a pair of first and second cell forming regions 11, 12 and a pair of third and fourth cell forming regions 13, 14. The first and second cell forming regions 11, 12 are aligned in a first direction B, the third and fourth cell forming regions 13, 14 are aligned in the first direction B, the first and third cell forming regions 11, 13 are aligned in a second direction W transverse to the first direction B, and the second and fourth cell forming regions 12, 14 are aligned in the second direction W. The isolation structure 2 includes first and second isolation strips 21, 22 embedded from the circuit-forming surface 10 and aligned in the second direction W. The first isolation strip 21 is disposed between the first and third cell forming regions 11, 13, the second isolation strip 22 is disposed between the second and fourth cell forming regions 12, 14, and the first and second isolation strips 21, 22 respectively have distal ends 211, 221 that are adjacent to each other and that are disconnected from each other to define an isolation-structure-free gap 23 therebetween. The isolation-structure-free gap 23 is filled with a material of the semiconductor substrate 1. The isolation structure 2 further defines a common-source forming region 16 on the circuit-forming surface 10 of the semiconductor substrate 1. The common-source forming region 16 is defined by first and second imaginary lines I, II each extending in the second direction W and passing through the distal end 211, 221 of a respective one of the first and second isolation strips 21, 22. The common-source forming region 16 is contiguous with the first, second, third and fourth cell forming regions 11, 12, 13, and 14.

The gate structure array 3 includes a plurality of gate structures 30, each disposed on top of the circuit-forming surface 10 above a respective one of the first, second, third and fourth cell forming regions 11, 12, 13, and 14 and each having a first side 301 adjacent to the common-source forming region 16 and a second side 302 opposite to the first side 301.

Each of the drain regions 4 is formed at the second side 302 of a respective one of the gate structures 30. The common source region 5 is formed at the common-source forming region 16 and extends to the first sides 302 of the gate structures 30.

As shown in FIG. 6, the isolation structure 2 further defines a source contact forming region 52 on the circuit-forming surface 10 of the semiconductor substrate 1, and the common source contact 51 is disposed at the source contact forming region 52. To be specific, the isolation structure 2 further includes boundary isolation strips 23 on outer lateral sides of the first, second, third and fourth cell forming regions 11, 12, 13, and 14, and the source contact forming region 52 is disposed outwardly with respect to the boundary isolation strips 23. By disposing the common source contact 51 as such, the source contact forming region 52 may be prevented from hindering an increase in the density of memory cells of the non-volatile memory device of this invention.

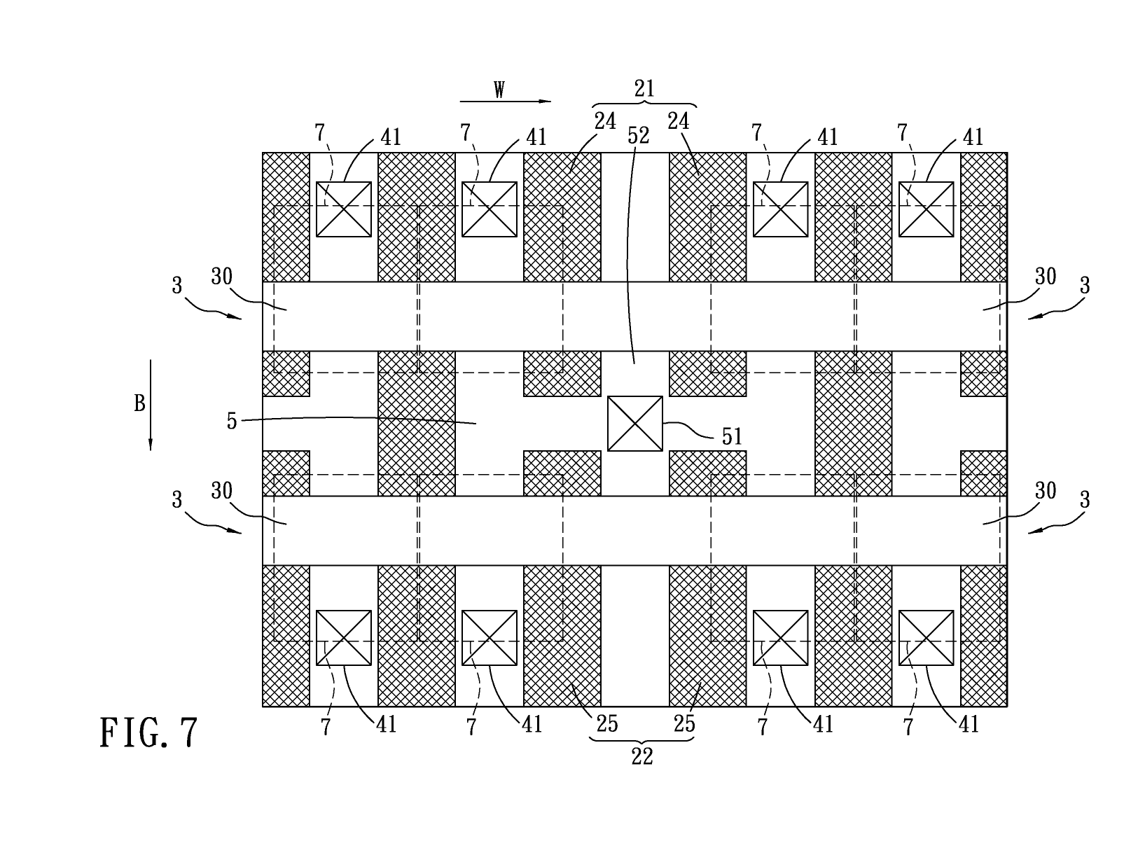

As shown in FIG. 7, the source contact forming region 52 may be defined among a parallel pair of first sub-strips 24 that constitute the first isolation strip 21, and a parallel pair of second sub-strips 25 that constitute the second isolation strip 22.

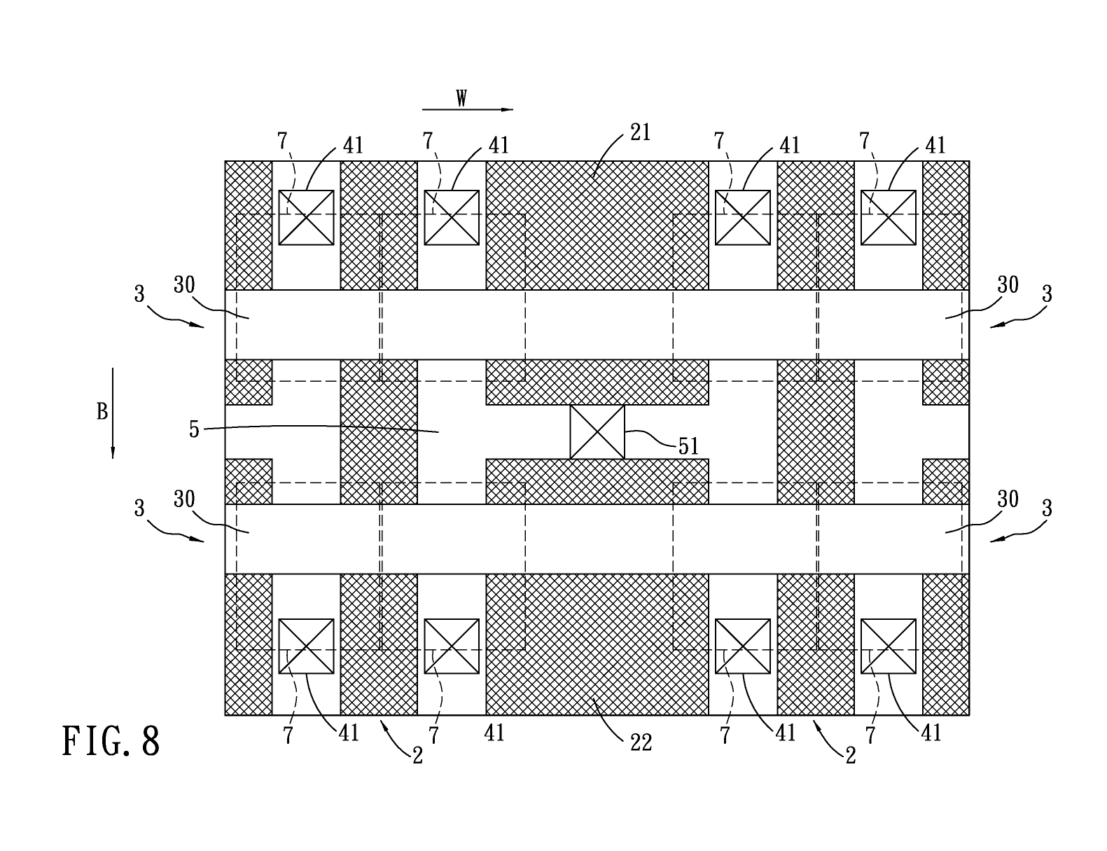

FIG. 8 differs from FIG. 7 in that the first and second isolation strips 21, 22 are both relatively wide unitary strips, and that the source contact forming region 52 is defined to be between the distal ends of the first and second isolation strips 21, 22.

Compared to the aforementioned prior art, where each memory cell has its own drain and source contacts, the non-volatile memory device of this invention uses a common source contact for a common source region that is common to a plurality of memory cells. By reducing the number of source contacts, fabrication costs and complexity may be reduced.

### Programming Step:

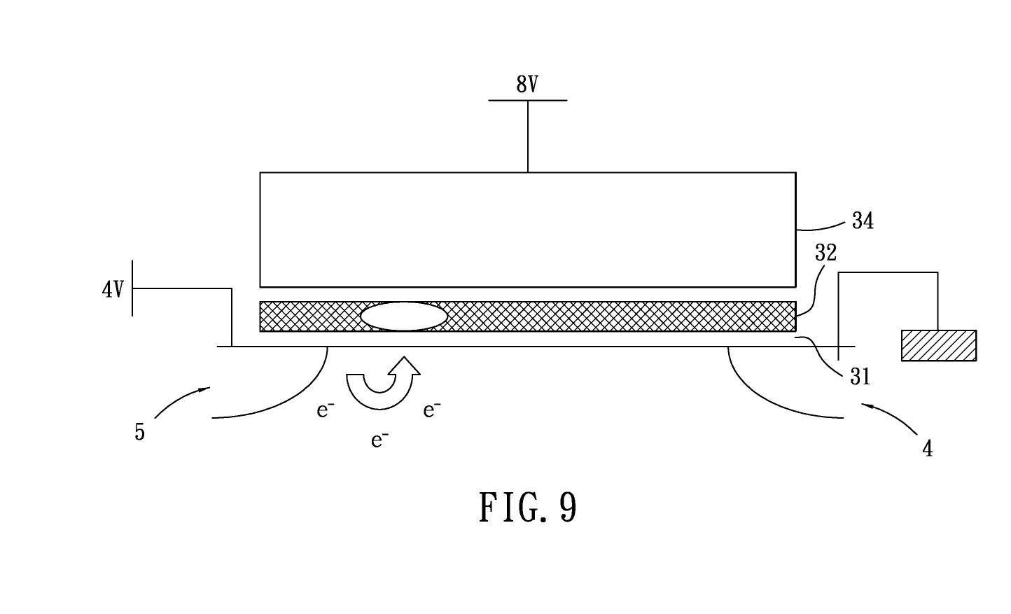

As shown in FIG. 9, in this embodiment, a channel hot electron injection method is performed for injecting electrons into the charge trapping layer 32 of the gate structure 30 while programming the memory cells 7 of the non-volatile memory device according to the present invention. For example, when +8 volts of voltage is applied to the gate layer 34 of one of the gate structures 30 and +4 volts of voltage is applied to the common source region 5, electrons are attracted to tunnel through the tunneling dielectric layer 31 and accumulate in the charge trapping layer 32 accordingly. Once the electrons are accumulated in the charge trapping layer 32 to a predetermined level, the programming process of the respective memory cell 7 is finished.

### Erasing Step:

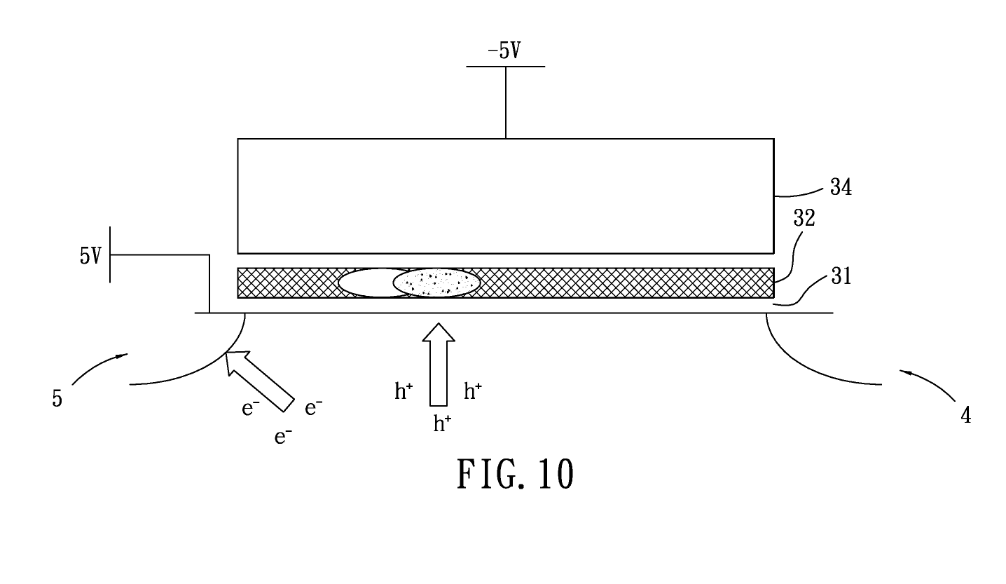

Referring to FIG. 10, in this embodiment, a band-to-band hot-hole (BBHH) injection method is performed for injecting electron holes into the charge trapping layer 32 for the erasing step. For example, when a voltage of −5 volts is applied to the gate layer 34 of one of the memory cells 7 and a voltage of +5 volts is applied to the common source region 5, electron holes are attracted to tunnel through the tunneling dielectric layer 31 to the charge trapping layer 32 and combined with the electrons therein. Once all the excess electrons in the charge trapping layer 32 are combined with the electron holes, the erasing step is finished.

### Reading Step:

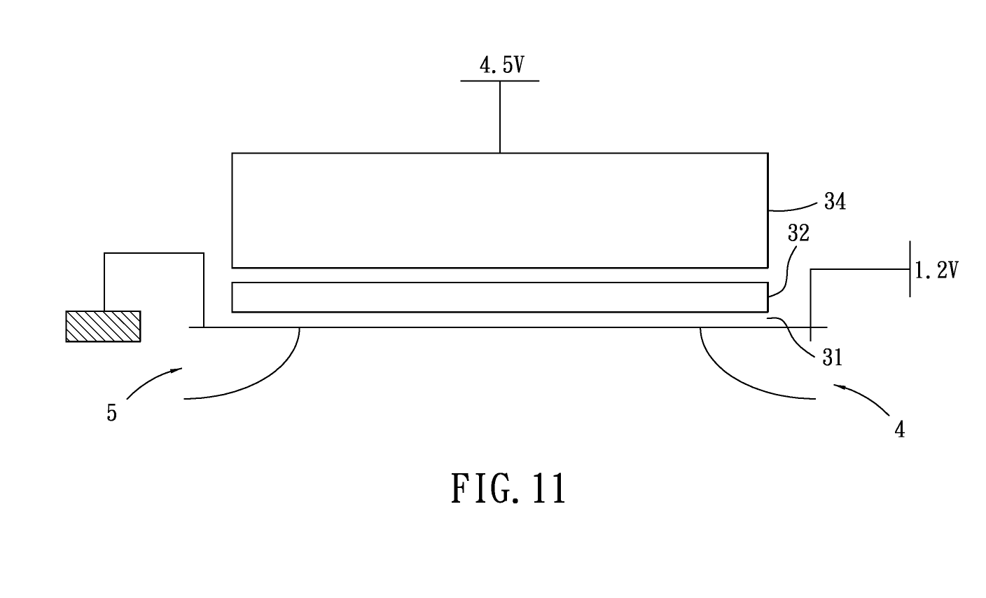

Referring to FIG. 11, in this embodiment, the reading step is to apply a voltage of +4.5 volts to the gate layer 34 of one of the memory cells 7 and a voltage of +1.2 volts to the respective drain region 4. It should be noted that the voltage applied to the gate layer 34 in the reading step is lower than that in the programming step.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A method for forming a non-volatile memory device, comprising:
a) forming an isolation structure on a circuit-forming surface of a semiconductor substrate to define an array of cell forming regions, the cell forming regions including a pair of first and second cell forming regions and a pair of third and fourth cell forming regions, the first and second cell forming regions being aligned in a first direction, the third and fourth cell forming regions being aligned in the first direction, the first and third cell forming regions being aligned in a second direction transverse to the first direction, the second and fourth cell forming regions being aligned in the second direction, the isolation structure including first and second isolation strips embedded from the circuit-forming surface of the semiconductor substrate and aligned in the second direction, the first isolation strip being disposed between the first and third cell forming regions, the second isolation strip being disposed between the second and fourth cell forming regions, the first and second isolation strips respectively having distal ends that are adjacent to each other and that are disconnected from each other to define an isolation-structure-free gap therebetween, the isolation-structure-free gap being filled with a material of the semiconductor substrate, the isolation structure further defining a common-source forming region on the circuit-forming surface of the semiconductor substrate, the common-source forming region being defined by first and second imaginary lines each extending in the second direction and passing through the distal end of a respective one of the first and second isolation strips, the common-source forming region being contiguous with the first, second, third and fourth cell forming regions;
b) forming a gate structure array on the circuit-forming surface of the semiconductor substrate, the gate structure array including a plurality of gate structures, each disposed on top of the circuit-forming surface of the semiconductor substrate above a respective one of the first, second, third and fourth cell forming regions and each having a first side adjacent to the common-source forming region and a second side opposite to the first side;
c) performing ion implantation to form drain regions and a common source region on the circuit-forming surface of the semiconductor substrate, each of the drain regions being formed at the second side of a respective one of the gate structures, the common source region being formed at the common-source forming region and extending to the first sides of the gate structures; and
d) forming drain contacts for external electrical connection to the drain regions, and a common source contact for external electrical connection to the common source region.

2. The method as claimed in claim 1, wherein step b) includes:
forming a tunneling dielectric layer, a charge trapping layer, a dielectric layer and a gate layer in sequence on the circuit-forming surface of the semiconductor substrate, wherein the tunneling dielectric layer, the charge trapping layer and the dielectric layer cooperatively form an Oxide-Nitride-Oxide multi-layer structure, and wherein the gate layer is formed on the dielectric layer; and
etching the tunneling dielectric layer, the charge trapping layer, the dielectric layer and the gate layer to form the gate structure array.

3. A non-volatile memory device, comprising:
a semiconductor substrate having a circuit-forming surface;
an isolation structure formed on the circuit-forming surface to define an array of cell forming regions thereon, the cell forming regions including a pair of first and second cell forming regions and a pair of third and fourth cell forming regions, the first and second cell forming regions being aligned in a first direction, the third and fourth cell forming regions being aligned in the first direction, the first and third cell forming regions being aligned in a second direction transverse to the first direction, the second and fourth cell forming regions being aligned in the second direction, the isolation structure including first and second isolation strips embedded from the circuit-forming surface and aligned in the second direction, the first isolation strip being disposed between the first and third cell forming regions, the second isolation strip being disposed between the second and fourth cell forming regions, the first and second isolation strips respectively having distal ends that are adjacent to each other and that are disconnected from each other to define an isolation-structure-free gap therebetween, the isolation-structure-free gap being filled with a material of the semiconductor substrate, the isolation structure further defining a common-source forming region on the circuit-forming surface of the semiconductor substrate, the common-source forming region being defined by first and second imaginary lines each extending in the second direction and passing through the distal end of a respective one of the first and second isolation strips, the common-source forming region being contiguous with the first, second, third and fourth cell-forming regions;
a gate structure array formed on the circuit-forming surface of the semiconductor substrate, the gate structure array including a plurality of gate structures, each disposed on top of the circuit-forming surface above a respective one of the first, second, third and fourth cell forming regions and each having a first side adjacent to the common-source forming region and a second side opposite to the first side;
drain regions and a common source region formed on the semiconductor substrate, each of the drain regions being formed at the second side of a respective one of the gate structures, the common source region being formed at the common-source forming region and extending to the first sides of the gate structures; and
drain contacts for external electrical connection to the drain regions, and a common source contact for external electrical connection to the common source region.

4. The non-volatile memory device as claimed in claim 3, wherein each of the gate structures includes a tunneling dielectric layer, a charge trapping layer, a dielectric layer and a gate layer formed in sequence on the circuit-forming surface of the semiconductor substrate, wherein the tunneling dielectric layer, the charge trapping layer and the dielectric layer cooperatively form an Oxide-Nitride-Oxide multi-layer structure, and wherein the gate layer is formed on the dielectric layer.

5. The non-volatile memory device as claimed in claim 3, wherein the isolation structure further defines a source contact forming region on the circuit-forming surface of the semiconductor substrate, the common source contact being disposed at the source contact forming region, the isolation structure further including boundary isolation strips on outer lateral sides of the first, second, third and fourth cell forming regions, the source contact forming region being disposed outwardly with respect to the boundary isolation strips.

6. The non-volatile memory device as claimed in claim 3, wherein the first isolation strip is constituted by a parallel pair of first sub-strips, the second isolation strip being constituted by a parallel pair of second sub-strips, the first and second sub-strips cooperatively defining a source contact forming region on the circuit-forming surface thereamong, the common source contact being disposed at the source contact forming region.

7. The non-volatile memory device as claimed in claim 3, wherein the distal ends of the first and second isolation strips define a source contact forming region on the circuit-forming surface therebetween, the common source contact being disposed at the source contact forming region.
